(19) United States
(12) Patent Application Publication
(10) Pub. No.: US 2026/0255549 A1
(43) Pub. Date: Aug. 27, 2026

(54) HEAT DISSIPATION DEVICE AND SERVER

(71) Applicants: Inventec (Pudong) Technology Corporation, Shanghai (CN); INVENTEC CORPORATION, Taipei (TW)

(72) Inventor: Congcong Xing, Shanghai (CN)

(21) Appl. No.: 19/207,420

(22) Filed: May 14, 2025

(30) Foreign Application Priority Data
Feb. 25, 2025 (CN) 202510213863.5

(51) Int. Cl. H05K 7/20

(52) U.S. Cl. CPC H05K 7/20772

(57) ABSTRACT

A heat dissipation device includes a cover body having a first side and a second side, a mounting member and a cooling member. The first side is provided with a cooling groove. The second side is provided with a first communication hole and a second communication hole. A side of the mounting member is provided with a first liquid cooling groove and a second liquid cooling groove. The first liquid cooling groove and the second side enclose a first liquid cooling cavity. The second liquid cooling groove and the second side enclose a second liquid cooling cavity. The cooling member and the cooling groove enclose a cooling cavity. At least two of a projection of the cooling cavity onto an element to be cooled, a projection of the first liquid cooling cavity onto the element, and a projection of the second liquid cooling cavity onto the element are misaligned.

### CROSS-REFERENCE TO RELATED APPLICATIONS

This application claims priority of Chinese Patent Application No. 202510213863.5, filed on Feb. 25, 2025, entitled “HEAT DISSIPATION DEVICE AND SERVER”, the entire content of which is incorporated herein by reference in its entirety.

### TECHNICAL FIELD

The present disclosure relates to the technical field of heat dissipation, and in particular to a heat dissipation device and a server.

### BACKGROUND

With the development of AI technology, the power consumption of GPU chips is increasing, resulting in more and more heat. In the conventional technology, a cooling plate is usually used to dissipate heat from the GPU. However, the conventional cooling plate cannot provide targeted heat dissipation to high heat generating areas of the GPU, resulting in poor heat dissipation effect on the GPU and affecting the computing speed of the GPU.

### SUMMARY

Accordingly, it is necessary to provide a heat dissipation device and a server to address the problem that the conventional cooling plate has a poor heat dissipation effect on the GPU and affects the computing speed of the GPU.

The technical solution is as follows:

One embodiment of the present disclosure provides a heat dissipation device, including:
a cover body having a first side and a second side opposite to each other, wherein th first side is provided with a cooling groove and is configured to be connected to an element to be cooled, and the second side is provided with a first communication hole and a second communication hole that are both in communication with the cooling groove;
a mounting member assembled with the second side, wherein a side of the mounting member facing the cover body is provided with a first liquid cooling groove and a second liquid cooling groove, the first liquid cooling groove and the second side enclose a first liquid cooling cavity, the second liquid cooling groove and the second side enclose a second liquid cooling cavity, the first liquid cooling cavity is in communication with the first communication hole, the second liquid cooling cavity is in communication with the second communication hole, the mounting member is further provided with a first liquid transmission opening and a second liquid transmission opening, the first liquid transmission opening is in communication with the first liquid cooling cavity, and the second liquid transmission opening is in communication with the second liquid cooling cavity; and
a cooling member assembled with the first side, wherein the cooling member and the cooling groove enclose a cooling cavity, and at least two of a projection of the cooling cavity onto the element to be cooled, a projection of the first liquid cooling cavity onto the element to be cooled, and a projection of the second liquid cooling cavity onto the element to be cooled are misaligned.

Another embodiment of the present disclosure provides a server, which includes an element to be cooled and the heat dissipation device as described above, wherein the heat dissipation device is provided on the element to be cooled.

The details of one or more embodiments of the application are set forth in the accompanying drawings and the description below. Other features, objects, and advantages of the application will be apparent from the description and drawings, and from the claims.

### BRIEF DESCRIPTION OF THE DRAWINGS

In order to illustrate the technical solutions in the embodiments of the present disclosure or the conventional technology more clearly, the following will briefly describe the accompanying drawings that will be used in the description of the embodiments or the traditional technology. It is clear that the accompanying drawings in the following description are only some embodiments of the present disclosure. For those skilled in the art, other drawings can also be obtained based on these drawings without creative effort.

FIG. 1 is a perspective view of a heat dissipation device according to an embodiment of the present disclosure.

FIG. 2 is an exploded view of a heat dissipation device according to an embodiment of the present disclosure.

FIG. 3 is an exploded view of a heat dissipation device viewed from another aspect according to an embodiment of the present disclosure.

FIG. 4 is a perspective view of a mounting member according to an embodiment of the present disclosure.

FIG. 5 is a perspective view of a cover body viewed from a second side according to another embodiment of the present disclosure.

FIG. 6 is a perspective view of a cover body viewed from a first side according to another embodiment of the present disclosure.

FIG. 7 is a top view of a mounting member according to another embodiment of the present disclosure.

FIG. 8 is a top view of a mounting member according to yet another embodiment of the present disclosure.

### DESCRIPTION OF REFERENCE NUMERALS

10. Heat dissipation device; 100. Cover body; 110. First side; 111. Cooling groove; 112. Cooling cavity; 120. Second side; 121. First communication hole; 122. Second communication hole; 200. Mounting member; 210. First liquid cooling groove; 211. First liquid cooling cavity; 212. First flow diversion portion; 220. Second liquid cooling groove; 221. Second liquid cooling cavity; 222. Second flow diversion portion; 231. First liquid transmission opening; 232. Second liquid transmission opening; 240. First flow groove; 241. First flow channel; 250. Second flow groove; 251. Second flow channel; 300. Cooling element; 310. Cooling plate; 320. Shovel-tooth heat sink; 400. First heat exchange mechanism; 410, First fin group; 420, Blocking member; 430, Heat exchange channel; 500, Second heat exchange mechanism; 510, Second fin group; 20, Element to be cooled; 21, First area; 22, Second area; 23, Third area.

### DETAILED DESCRIPTION OF THE EMBODIMENTS

In order to make the above objectives, features and advantages of the present disclosure clear and easier to understand, the specific embodiments of the present disclosure are described in detail below in combination with the accompanying drawings. Many specific details are set forth in the following description to facilitate a full understanding of the present disclosure. However, the present disclosure can be implemented in many ways different from those described herein, and those skilled in the art can make similar improvements without departing from the connotation of the present disclosure. Therefore, the present disclosure is not limited by the specific embodiments disclosed below.

In the description of the present disclosure, it should be understood that the terms “center”, “longitudinal”, “transverse”, “length”, “width”, “thickness”, “upper”, “lower”, “front”, “rear”, “left”, “right”, “vertical”, “horizontal”, “top”, “bottom”, “inner”, “outer”, “clockwise”, “counterclockwise”, “axial”, “radial”, “circumferential direction” are based on the azimuths or position relationships shown in the attached drawings. These terms are only for the convenience of describing the present disclosure and simplifying the description, rather than indicating or implying that the indicated devices or elements must have the specific azimuths, or be constructed or operated in the specific azimuths, and therefore such terms cannot be understood as limitations of the present disclosure.

In addition, the terms “first” and “second” are only used for descriptive purposes and cannot be understood as indicating or implying relative importance or implicitly indicating the number of indicated technical features. Thus, the features defined with “first” and “second” may explicitly or implicitly include at least one of the features. In the description of the present disclosure, “a plurality of” means at least two, such as two, three, etc., unless otherwise expressly and specifically defined.

In the present disclosure, unless otherwise expressly specified and limited, the terms “mount”, “connect”, “couple”, “fix” and the like should be interpreted broadly. For example, the terms can mean fixed connection, detachable connection, or being integrated. The terms can mean mechanical connection or electrical connection. The terms can mean directly connection or indirectly connection through an intermediate medium. The terms can mean connection within two elements or interaction relationship between two elements, unless otherwise expressly limited. For those skilled in the art, the specific meaning of the above terms in the present disclosure should be understood according to the specific situation.

In the present disclosure, unless otherwise expressly specified and limited, a first feature “above” or “below” a second feature may be in direct contact with the second feature, or the first and second features may be in indirect contact through an intermediate medium. Moreover, the first feature “above” the second feature may be right above or obliquely above the second feature, or the first feature may be merely located at a height higher than the second feature. The first feature “below” the second feature may be right below or obliquely below the second feature, or the first feature may be merely located at a height lower than that of the second feature.

It should be noted that when an element is called “fixed to” or “mounted on” another element, it can be directly on another element or there can be an intermediate element. When an element is considered to be “connected” to another element, it can be directly connected to another element or there can be an intermediate element. The terms “vertical”, “horizontal”, “up”, “down”, “left”, “right” and similar expressions used herein are for the purpose of illustration only and do not represent the only ways for implementation.

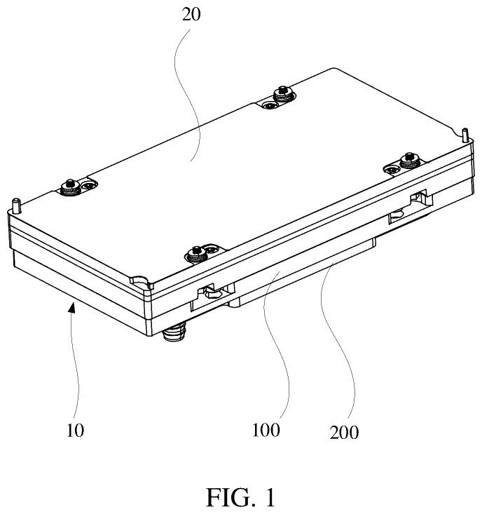

Referring to FIG. 1 to FIG. 4, an embodiment of the present disclosure provides a heat dissipation device 10, including a cover body 100, a mounting member 200, and a cooling member 300.

The cover body 100 has a first side 110 and a second side 120 opposite to each other. The first side 110 is provided with a cooling groove 111 and is configured to be connected to an element 20 to be cooled. The second side 120 is provided with a first communication hole 121 and a second communication hole 122 that are both in communication with the cooling groove 111.

The mounting member 200 is assembled with the second side 120. A side of the mounting member 200 facing the cover body 100 is provided with a first liquid cooling groove 210 and a second liquid cooling groove 220. The first liquid cooling groove 210 and the second side 120 enclose a first liquid cooling cavity 211. The second liquid cooling groove 220 and the second side 120 enclose a second liquid cooling cavity 221. The first liquid cooling cavity 211 is in communication with the first communication hole 121, and the second liquid cooling cavity 221 is in communication with the second communication hole 122. The mounting member 200 is further provided with a first liquid transmission opening 231 and a second liquid transmission opening 232, the first liquid transmission opening 231 is in communication with the first liquid cooling cavity 211, and the second liquid transmission opening 232 is in communication with the second liquid cooling cavity 221.

The cooling member 300 is assembled with the first side 110, and the cooling member 300 and the cooling groove 111 enclose a cooling cavity 112. At least two of a projection of the cooling cavity 112 onto the element 20 to be cooled, a projection of the first liquid cooling cavity 211 onto the element 20 to be cooled, and a projection of the second liquid cooling cavity 221 onto the element 20 to be cooled are misaligned.

According to the heat dissipation device 10, the cooling groove 111 is provided on the first side 110 of the cover body 100, the cooling member 300 covers the cooling groove 111 to form the cooling cavity 112 on the first side 110, and the second side 120 of the cover body 100 covers the first liquid cooling groove 210 and the second liquid cooling groove 220 to for the first liquid cooling cavity 211 and the second liquid cooling cavity 221 on the second side 120. Cooling liquid enters the first liquid cooling cavity 211 from the first liquid transmission opening 231, and enters the cooling cavity 112 through the first communication hole 121, then enters the second cooling cavity 112 through the second communication hole 122, and is finally discharged through the second liquid transmission opening 232. When the first side 110 of the cover body 100 is connected to the element 200 to be cooled, since at least two of the projection of the cooling cavity 112 onto the element 20 to be cooled, the projection of the first liquid cooling cavity 211 onto the element 20 to be cooled, and the projection of the second liquid cooling cavity 221 onto the element to be cooled 20 are misaligned, a more stable heat dissipation effect can be provided to the element 20 to be cooled. In addition, since the cooling cavity 112 is located on the first side 110 of the cover body 100, the heat dissipation device 10 can achieve more sufficient heat dissipation for an area of the element 20 to be cooled corresponding to the cooling element 300. Compared with the conventional technology, the heat dissipation device 10 can provide targeted heat dissipation to a high heat generating area of the element 20 to be cooled, which can improve the heat dissipation effect on the element 20 to be cooled, and ensure that the element 20 to be cooled can be at a normal operating temperature and operate normally.

As an explanation, since the cooling cavity 112 is located on the first side 110 of the cover body 100, and the first liquid cooling cavity 211 and the second liquid cooling cavity 221 are located on the second side 120 of the cover body 100, when the element 20 to be cooled is assembled with the first side 110 of the cover body 100, the cooling cavity 112 is closer to the element 20 to be cooled than the first liquid cooling cavity 211 and the second liquid cooling cavity 221, thereby achieving more sufficient heat dissipation for the area of the element 20 to be cooled corresponding to the cooling element 300.

Further, the projection of the cooling cavity 112 onto the element 20 to be cooled, the projection of the first liquid cooling cavity 211 onto the element 20 to be cooled, and the projection of the second liquid cooling cavity 221 onto the element 20 to be cooled are misaligned, thereby providing a more reliable heat dissipation effect for the element 20 to be cooled.

As a further explanation, at least two of the projection of the cooling cavity 112 onto the element 20 to be cooled, the projection of the first liquid cooling cavity 211 onto the element 20 to be cooled, and the projection of the second liquid cooling cavity 221 onto the element 20 to be cooled are misaligned, which means that any two of the three projections may partially overlap, or all three projections may be misaligned with one another, and it can be flexibly selected according to the requirements of the element 20 to be cooled, which is not specifically limited herein.

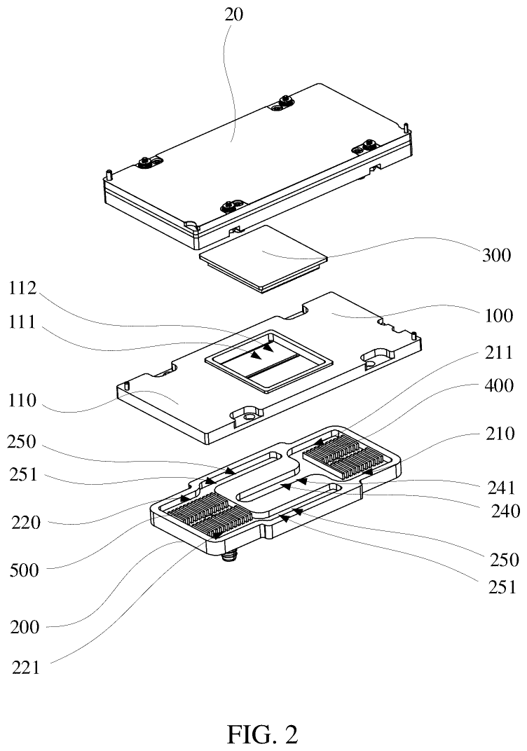

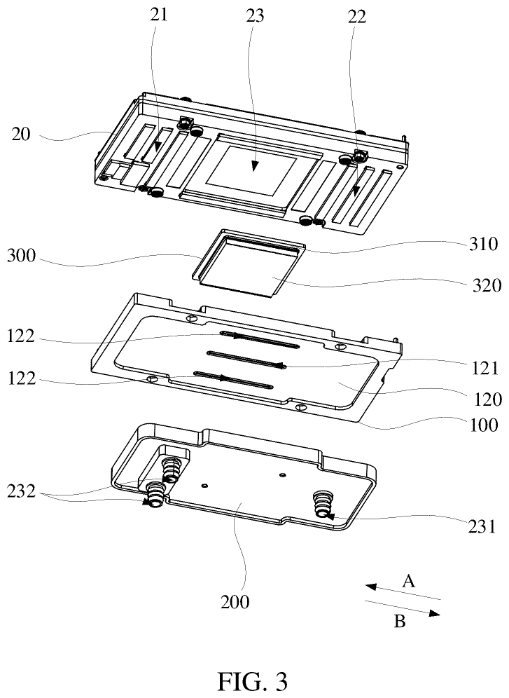

Referring to FIG. 2 and FIG. 3, in an embodiment, the element 20 to be cooled has a first area 21, a second area 22 and a third area 23. The first area 21 is a projection area of the first liquid cooling cavity 211 onto the element 20 to be cooled. The second area 22 is a projection area of the second liquid cooling cavity 221 onto the element 20 to be cooled. The third area 23 is a projection area of the cooling cavity 112 onto the element 20 to be cooled. The first area 21, the second area 22, and the third area 23 are misaligned. Generally, the third area 23 is a core heat generating area of the element 20 to be cooled. For example, when the element 20 to be cooled is a video card, the third area 23 is an area where a GPU chip is located. For another example, when the element 20 to be cooled is a computer motherboard, the third area 23 is an area where the CPU chip is located. In the above embodiment, the cooling cavity 112 located on the first side 110 of the cover body 100 is closer to the element 20 to be cooled than the first liquid cooling cavity 211 and the second liquid cooling cavity 221 located on the second side 120 of the cover body 100. Therefore, when the cooling liquid flows through the cooling cavity 112, the core heat generating area of the element 20 to be cooled, that is, the third area 23 can be fully cooled, and the heat generated by the first area 21 and the second area 22 of the element 20 to be cooled is less than that of the third area 23. Therefore, the first liquid cooling cavity 211 and the second liquid cooling cavity 221 located on the second side 120 of the cover body 100 are used to dissipate heat from the first area 21 and the second area 22, respectively, and the heat dissipation design is reasonable and the heat dissipation effect is better.

As a supplementary explanation, the cooling capacity carried by the cooling liquid with the same flow rate is limited, in order to ensure that most of the cooling capacity carried by the cooling liquid can exchange heat with the third area 23 of the element 20 to be cooled, when the cooling liquid enters the first liquid cooling cavity 211 through the first liquid transmission opening 231, since the first liquid cooling cavity 211 is located on the second side 120 of the cover body 100 and the heat generated by the first area 21 is relatively small, when the cooling liquid flows through the first liquid cooling cavity 211, the heat exchanged between the cooling liquid and the first area 21 is relatively small, the cooling liquid still carries a relatively high cooling capacity when entering the cooling cavity 112 through the first liquid cooling cavity 211, which ensures that most of the cooling capacity in the cooling liquid can exchange heat with the third area 23. The cooling liquid finally enters the second liquid cooling cavity 221. At this time, the cooling capacity carried by the cooling liquid is greatly reduced. However, since the heat generated by the second area 22 is relatively small, even if the cooling capacity carried by the cooling liquid in the second liquid cooling cavity 221 is relatively small, the second area 22 can be fully cooled.

In an embodiment, the cooling member 300 is plate-shaped and can cover the cooling groove 111, thereby enclosing the cooling cavity 112 together with the cooling groove 111. The side of the cooling member 300 away from the cooling groove 111 can be in contact with the heat dissipation member 20. The cooling liquid in the cooling cavity 112 can exchange heat with the heat dissipation member 20 through the cooling member 300, thereby cooling the third area 23 of the heat dissipation member 20.

In addition, the cover body 100, the mounting member 200, and the cooling member 300 are separately provided, so that the cover body 100, the mounting member 200, and the cooling member 300 can be separately and modularly produced during production, and then assembled after production, thereby improving production efficiency and reducing production cost.

Referring to FIG. 3, in an embodiment, the first liquid transmission opening 231 and the second liquid transmission opening 232 are formed on a side of the mounting member 200 away from the cover body 100.

Further, the number of the first liquid transmission opening 231 and the second liquid transmission opening 232 is not limited, which can be flexibly set according to actual working conditions, and is not specifically limited herein.

Optionally, in some embodiments, the first liquid transmission opening 231 may be either a liquid inlet or a liquid outlet, and correspondingly, the second liquid transmission opening 232 may be either a liquid outlet or a liquid inlet.

Referring to FIGS. 1 to 3, in an embodiment, the mounting member 200 is plate-shaped that adapted to the cover body 100.

Referring to FIG. 2 to FIG. 4, in an embodiment, the mounting member 200 is provided with a first flow groove 240 in communication with the first liquid cooling groove 210. The first flow groove 240 and the second side 120 enclose a first flow channel 241. The first communication hole 121 is a strip-shaped through hole. A first extending direction of the first communication hole 121 is the same as an extending direction of the first flow channel 241, and the first communication hole 121 in communication with the first flow channel 241.

The second side 120 of the cover body 100 covers the first flow groove 240, thereby forming the first flow channel 241 on the second side 120. In this way, after entering the first flow channel 241, the cooling liquid can enter the cooling cavity 112 through the first communication hole 121. The first extending direction of the first communication hole 121 is the same as the extending direction of the first flow channel 241, thereby forming the strip-shaped through hole. Such configuration can not only increase the speed of the cooling liquid entering the cooling cavity 112 from the first flow channel 241 through the strip-shaped through hole, but also improve the flow uniformity of the cooling liquid entering the cooling cavity 112 from the strip-shaped through hole, thereby improving the heat dissipation effect of the cooling liquid in the cooling cavity 112 on the element 20 to be cooled.

As an explanation, the first extending direction in the above embodiment is a length direction of the first communication hole 121 (i.e., a direction A in FIG. 3).

Further, the cooling liquid enters the first flow channel 241 and flows in the first flow channel 241 to dissipate heat in the area of the element 20 to be cooled corresponding to the first flow channel 241. Therefore, during the production of the heat dissipation device 10, an extending direction of the first flow groove 240 may be designed according to the heat generating area of the element 20 to be cooled, thereby ensuring the heat dissipation effect of the cooling liquid flowing in the first flow channel 241 on the element 20 to be cooled.

Referring to FIG. 2 to FIG. 4, in an embodiment, the mounting member 200 is provided with a second flow groove 250 in communication with the second liquid cooling groove 220. The second flow groove 250 and the second side 120 enclose a second flow channel 251. The second communication hole 122 is a strip-shaped through hole. A second extending direction of the second communication hole 122 is the same as an extending direction of the second flow channel 251, and the second communication hole 122 is in communication with the second flow channel 251.

The second side 120 of the cover body 100 covers the second flow groove 250, thereby forming the second flow channel 251 on the second side 120. In this way, the cooling liquid in the cooling cavity 112 can enter the second flow channel 251 through the second communication hole 122, and enter the second liquid cooling cavity 221 from the second flow channel 251. The second extending direction of the second communication hole 122 is the same as the extending direction of the second flow channel 251, thereby forming the strip-shaped through hole. Such configuration can not only increase the speed of the cooling liquid entering the second liquid cooling cavity 221 from the second flow channel 251 through the strip-shaped through hole, but also improve the flow uniformity of the cooling liquid entering the second liquid cooling cavity 221 from the strip-shaped through hole, thereby improving the heat dissipation effect of the cooling liquid flowing in the second liquid cooling cavity 221 on the element 20 to be cooled.

As an explanation, the second extending direction in the above embodiment is a length direction of the second communication hole 122 (i.e., a direction B in FIG. 3).

Further, the cooling liquid enters the second flow channel 251 and flows in the second flow channel 251 to dissipate heat in the area of the element 20 to be cooled corresponding to the second flow channel 251. Therefore, during the production of the heat dissipation device 10, an extending direction of the second flow groove 250 may be designed according to the heat generating area of the element 20 to be cooled, thereby ensuring the heat dissipation effect of the cooling liquid flowing in the second flow channel 251 on the element 20 to be cooled.

Referring to FIG. 2 to FIG. 4, in an embodiment, at least two first flow grooves 240 are provided, and at least two first communication holes 121 are provided in one-to-one correspondence with the at least two first flow grooves 240.

Referring to FIG. 2 to FIG. 4, in an embodiment, at least two second flow grooves 250 are provided, and at least two second communication holes 122 are provided in one-to-one correspondence with the at least two second flow grooves 250.

Further, referring to FIG. 2 to FIG. 4, in an embodiment, one first flow groove 240 is provided, two second flow grooves 250 are provided, and the first flow groove 240 is located between the two second flow grooves 250. Correspondingly, one first communication hole 121 is provided corresponding to the first flow groove 240, and two second communication holes 122 are provided in one-to-one correspondence with the two second flow grooves 250. The two second communication holes 122 are located on both sides of the first communication hole 121, respectively. In this way, the cooling liquid enters the liquid cooling cavity through the first communication hole 121, and flows out of the liquid cooling cavity through the second communication holes 122 on both sides of the first communication hole 121. Under the premise that the total flow rate of the cooling liquid remains unchanged, a flow area of the cooling liquid flowing from one first communication hole 121 is smaller, so that the flow speed of the cooling liquid flowing into the liquid cooling cavity is greater, the Reynolds number increases, so that the Nusselt number increases, and the convective heat transfer coefficient increases accordingly. Therefore, the heat dissipation device 10 has a better heat dissipation effect on the position on the element 20 to be cooled corresponding to the liquid cooling cavity on the.

Further, the two second flow grooves 250 are provided on both sides of the first flow groove 240, respectively, so as to dissipate heat from a corner area of the element 20 to be cooled to ensure the heat dissipation effect on the element 20 to be cooled.

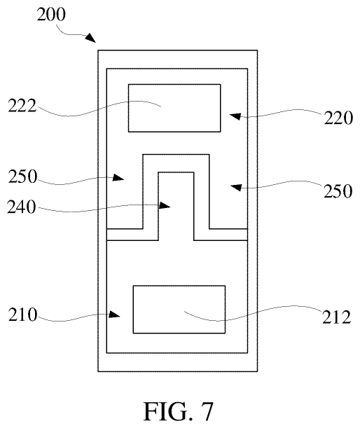

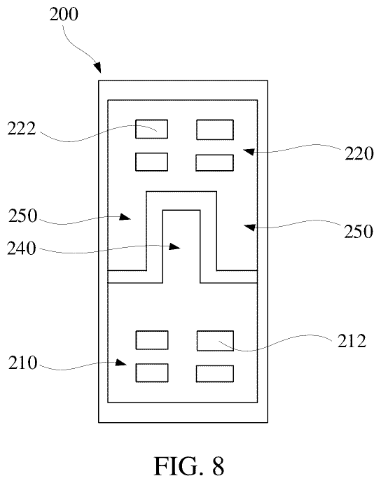

Referring to FIG. 7 and FIG. 8, in an embodiment, a first flow diversion portion 212 is provided in the first liquid cooling groove 210, and the first flow diversion portion 212 can divide the space in the first liquid cooling groove 210 into a plurality of branches, so that the flow process of the cooling liquid in the first liquid cooling cavity 211 is more complicated, and the cooling liquid in each branch collides with each other, which make the flow more intense, thereby increasing the local Reynolds number and further enhancing the heat exchange effect.

Referring to FIG. 7 and FIG. 8, in an embodiment, a second flow diversion portion 222 is provided in the second liquid cooling groove 220. The effect of the second flow diversion portion 222 is similar to that of the first flow diversion portion 212, which is not described herein again.

Further, in the embodiment shown in FIG. 8, the first flow diversion portion 212 can divide the space in the first liquid cooling groove 210 into a plurality of branches having a grid-like shape, and the cooling liquid collides with each other in the branches to further enhance the heat exchange effect. The second flow diversion portion 222 can divide the space in the second liquid cooling groove 220 into a plurality of branches having a grid-like shape, which is similar to the first flow diversion portion 212 and is not described herein again.

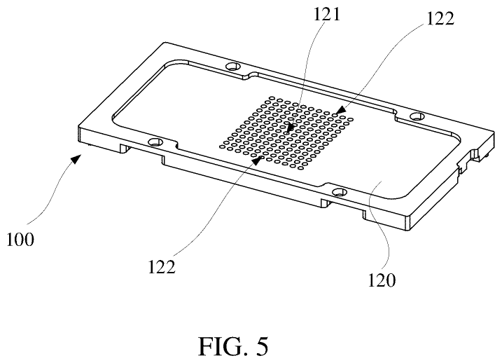

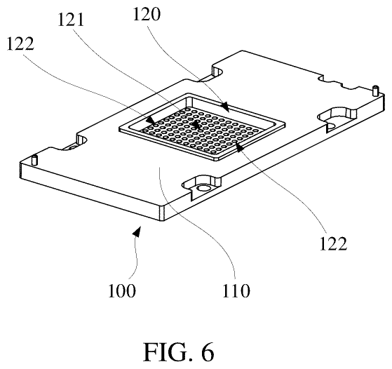

Referring to FIG. 5 and FIG. 6, in an embodiment, a plurality of first communication holes 121 are provided, a plurality of second communication holes 122 are provided, and all the first communication holes 121 and all the second communication holes 122 are combined to form a hole array structure. In this way, when the extending direction of the first liquid cooling groove 210 and the extending direction of the second liquid cooling groove 220 change, the hole array structure formed by the combination of the first communication hole 121 and the second communication hole 122 does not need to be changed, thereby achieving unified and standardized production of the cover body 100 and reducing the production cost.

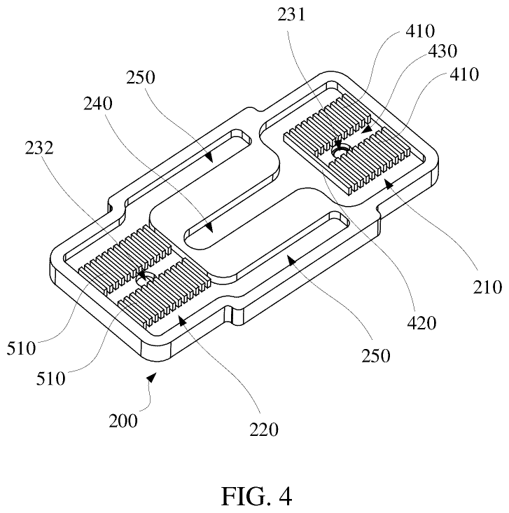

Referring to FIG. 2 and FIG. 4, in an embodiment, the heat dissipation device 10 further includes a first heat exchange mechanism 400. The first heat exchange mechanism 400 is provided in the first liquid cooling groove 210 and abuts against the second side 120.

The first heat exchange mechanism 400 can exchange heat with the cooling liquid in the first liquid cooling cavity 211. The first heat exchange mechanism 400 abuts against the second side 120, thereby achieving heat exchange with the second side 120 of the cover body 100, and further achieving heat exchange between the cooling liquid and the second side 120 of the cover body 100, and improving the heat exchange effect between the cooling liquid and the first area 21 of the element 20 to be cooled.

Optionally, the first heat exchange mechanism 400 may be a structure such as heat exchange fins, heat exchange teeth, etc. that can increase a heat exchange area with the cooling liquid, which is not specifically limited herein.

Further, the first heat exchange mechanism 400 can have a certain blocking and diverting effect on the cooling liquid, thereby further enhancing the heat exchange effect of the cooling liquid.

Referring to FIG. 4, in an embodiment, the first heat exchange mechanism 400 includes at least two first fin groups 410 provided around an outer periphery of the first liquid transmission opening 231.

With such configuration, when the cooling liquid enters the first liquid cooling groove 210 through the first liquid transmission opening 231, the cooling liquid can pass through the first fin group 410, so that the cooling liquid can fully exchange heat with the first fin group 410, thereby ensuring the cooling effect of the cooling liquid in the first liquid cooling cavity 211 has a heat dissipation effect on the first area 21 of the element 20 to be cooled.

Optionally, adjacent two first fin groups 410 may be spaced apart along a width direction of the mounting member 200, or may be spaced apart along a length direction of the mounting member 200, which is not specifically limited herein.

Further, the first fin group 410 includes at least two first fins. In some embodiments, adjacent two first fin groups 410 are spaced apart along the width direction of the mounting member 200, and all the first fins are spaced apart along the length direction of the mounting member 200. In other embodiments, adjacent two first fin groups 410 are spaced apart along the length direction of the mounting member 200, and all the first fins are spaced apart along the width direction of the mounting member 200.

Referring to FIG. 4, in an embodiment, the first heat exchange mechanism 400 further includes two first fin groups 410 and a blocking member 420. The two first fin groups 410 are spaced apart from each other to form a heat exchange channel 430. The blocking member 420 is located at at least one end of the heat exchange channel 430.

The cooling liquid enters the heat exchange channel 430 through the first communication hole 121. The blocking member 420 provided at at least one end of the heat exchange channel 430 can block the cooling liquid to prevent the cooling liquid from directly flowing out of the heat exchange channel 430, thereby ensuring that the cooling liquid can fully exchange heat with the first fin group 410, and further enhancing the heat exchange effect between the cooling liquid in the first liquid cooling groove 210 and the element 20 to be cooled.

Further, referring to FIG. 4, in an embodiment, an end of the heat exchange channel 430 faces the first flow groove 240, and the blocking member 420 is located between the end of the heat exchange channel 430 and the first flow groove 240, so as to prevent the cooling liquid entering the heat exchange channel 430 from the first communication hole 121 from directly entering the first flow channel 241, thereby ensuring that the cooling liquid can fully exchange heat with the first fin group 410.

In other embodiments, two blocking members 420 are provided, and the two blocking members 420 are provided at opposite ends of the heat exchange channel 430, respectively, so as to prevent the cooling liquid entering the heat exchange channel 430 from the first communication hole 121 from failing to fully exchange heat with the first fin group 410.

Referring to FIG. 2 and FIG. 4, in an embodiment, the heat dissipation device 10 further includes a second heat exchange mechanism 500. The second heat exchange mechanism 500 is provided in the second liquid cooling groove 220 and abuts against the second side 120.

The second heat exchange mechanism 500 can exchange heat with the cooling liquid in the second liquid cooling cavity 221. The second heat exchange mechanism 500 abuts against the second side 120, so as to exchange heat with the second side 120 of the cover body 100, thereby achieving the heat exchange between the cooling liquid and the second side 120 of the cover body 100, and improving the heat exchange effect between the cooling liquid and the second area 22 of the element 20 to be cooled.

Optionally, the second heat exchange mechanism 500 may be a structure such as heat exchange fins, heat exchange teeth, etc. that can increase a heat exchange area with the cooling liquid, which is not specifically limited herein.

Further, the second heat exchange mechanism 500 can have a certain blocking and diverting effect on the cooling liquid, thereby further enhancing the heat exchange effect of the cooling liquid.

Referring to FIG. 4, in an embodiment, the second heat exchange mechanism 500 includes at least two second fin groups 510 provided around an outer periphery of the second liquid transmission opening 232.

With such configuration, when the cooling liquid needs to be discharged from the second liquid cooling cavity 221 through the second liquid transmission opening 232, the cooling liquid needs to pass through the second fin group 510, so as to exchange heat fully with the second fin group 510, thereby ensuring the cooling effect of the cooling liquid in the second liquid cooling cavity 221 has a heat dissipation effect on the second area 22 of the element 20 to be cooled.

Optionally, adjacent two second fin groups 510 may be spaced apart along the width direction of the mounting member 200, or may be spaced apart along the length direction of the mounting member 200, which is not specifically limited herein.

Further, in the embodiment shown in FIG. 4, two second fin groups 510 are provided and are spaced apart along the width direction of the mounting member 200, and two second flow grooves 250 are provided. One second flow groove 250 is provided on a side of one second fin group 510 away from the second liquid transmission opening 232, and the other second flow groove 250 is provided on a side of the other second fin group 510 away from the second liquid transmission opening 232. In this way, when the cooling liquid in the cooling cavity 112 flows to the second liquid cooling cavity 221 through the two second flow channels 251, the cooling liquid will pass through the two second fin groups 510 and then flow out from the second liquid transmission opening 232, thereby ensuring sufficient heat exchange between the cooling liquid and the second fin group 510.

Further, the second fin group 510 includes at least two second fins. In some embodiments, adjacent two second fin groups 510 are spaced apart along the width direction of the mounting member 200, and all the second fins are spaced apart along the length direction of the mounting member 200. In other embodiments, the second fin groups 510 are spaced apart along the length direction of the mounting member 200, and all the second fins are spaced apart along the width direction of the mounting member 200.

Referring to FIG. 3, in an embodiment, the cooling member 300 includes a cooling plate 310 and a shovel-tooth heat sink 320. The cooling plate 310 and the cooling groove 111 enclose the cooling cavity 112. The shovel-tooth heat sink 320 are provided on a side of the cooling plate 310 and is located in the cooling cavity 112.

The arrangement of the shovel-tooth heat sink 320 can increase a heat exchange area between the cooling liquid and the cooling plate 310, which can improve the heat exchange efficiency between the cooling liquid and the element 20 to be cooled, and ensure the heat dissipation effect of the heat dissipation device 10 on the element 20 to be cooled.

Another embodiment of the present disclosure provides a server, which includes an element 20 to be cooled and the heat dissipation device 10 of any of the above embodiments. The heat dissipation device 10 is provided on the element 20 to be cooled.

According to the server, the cooling groove 111 is provided on the first side 110 of the cover body 100, the cooling member 300 covers the cooling groove 111 to form the cooling cavity 112 on the first side 110, and the second side 120 of the cover body 100 covers the first liquid cooling groove 210 and the second liquid cooling groove 220 to for the first liquid cooling cavity 211 and the second liquid cooling cavity 221 on the second side 120. Cooling liquid enters the first liquid cooling cavity 211 from the first liquid transmission opening 231, and enters the cooling cavity 112 through the first communication hole 121, then enters the second cooling cavity 112 through the second communication hole 122, and is finally discharged through the second liquid transmission opening 232. When the first side 110 of the cover body 100 is connected to the element 200 to be cooled, since at least two of the projection of the cooling cavity 112 onto the element 20 to be cooled, the projection of the first liquid cooling cavity 211 onto the element 20 to be cooled, and the projection of the second liquid cooling cavity 221 onto the element to be cooled 20 are misaligned, a more stable heat dissipation effect can be provided to the element 20 to be cooled. In addition, since the cooling cavity 112 is located on the first side 110 of the cover body 100, the heat dissipation device 10 can achieve more sufficient heat dissipation for an area of the element 20 to be cooled corresponding to the cooling element 300. Compared with the conventional technology, the heat dissipation device 10 can provide targeted heat dissipation to a high-heat generating area of the element 20 to be cooled, which can improve the heat dissipation effect on the element 20 to be cooled, and ensure that the element 20 to be cooled can be at a normal operating temperature and operate normally.

The above-mentioned embodiments do not constitute a limitation on the protection scope of the technical solution. Any modifications, equivalent replacements and improvements made within the spirit and principles of the above-mentioned embodiments shall be included within the protection scope of this technical solution.

The foregoing descriptions are merely specific embodiments of the present disclosure, but are not intended to limit the protection scope of the present disclosure. Any variation or replacement readily figured out by a person skilled in the art within the technical scope disclosed in the present disclosure shall all fall within the protection scope of the present disclosure.

What is claimed is:

1. A heat dissipation device, comprising:
a cover body having a first side and a second side opposite to each other, wherein the first side is provided with a cooling groove and is configured to be connected to an element to be cooled, and the second side is provided with a first communication hole and a second communication hole that are both in communication with the cooling groove;
a mounting member assembled with the second side, wherein a side of the mounting member facing the cover body is provided with a first liquid cooling groove and a second liquid cooling groove, the first liquid cooling groove and the second side enclose a first liquid cooling cavity, the second liquid cooling groove and the second side enclose a second liquid cooling cavity, the first liquid cooling cavity is in communication with the first communication hole, the second liquid cooling cavity is in communication with the second communication hole, the mounting member is further provided with a first liquid transmission opening and a second liquid transmission opening, the first liquid transmission opening is in communication with the first liquid cooling cavity, and the second liquid transmission opening is in communication with the second liquid cooling cavity; and
a cooling member assembled with the first side, wherein the cooling member and the cooling groove enclose a cooling cavity, and at least two of a projection of the cooling cavity onto the element to be cooled, a projection of the first liquid cooling cavity onto the element to be cooled, and a projection of the second liquid cooling cavity onto the element to be cooled are misaligned.

2. The heat dissipation device according to claim 1, wherein the mounting member is provided with a first flow groove in communication with the first liquid cooling groove, the first flow groove and the second side enclose a first flow channel, the first communication hole is a strip-shaped through hole, a first extending direction of the first communication hole is the same as an extending direction of the first flow channel, and the first communication hole is in communication with the first flow channel.

3. The heat dissipation device according to claim 1, wherein the mounting member is provided with a second flow groove in communication with the second liquid cooling groove, the second flow groove and the second side enclose a second flow channel, the second communication hole is a strip-shaped through hole, a second extending direction of the second communication hole is the same as an extending direction of the second flow channel, and the second communication hole is in communication with the second flow channel.

4. The heat dissipation device according to claim 1, further comprising a first heat exchange mechanism, wherein the first heat exchange mechanism is provided in the first liquid cooling groove and abuts against the second side.

5. The heat dissipation device according to claim 4, wherein the first heat exchange mechanism comprises at least two first fin groups provided around an outer periphery of the first liquid transmission opening.

6. The heat dissipation device according to claim 4, wherein the first heat exchange mechanism further comprises two first fin groups and a blocking member, the two first fin groups are spaced apart from each other to form a heat exchange channel, and the blocking member is located at at least one end of the heat exchange channel.

7. The heat dissipation device according to claim 1, further comprising a second heat exchange mechanism, wherein the second heat exchange mechanism is provided in the second liquid cooling groove and abuts against the second side.

8. The heat dissipation device according to claim 7, wherein the second heat exchange mechanism comprises at least two second fin groups provided around an outer periphery of the second liquid transmission opening.

9. The heat dissipation device according to claim 1, wherein the cooling member comprises a cooling plate and a shovel-tooth heat sink, the cooling plate and the cooling groove enclose the cooling cavity, and the shovel-tooth heat sink are provided on a side of the cooling plate and is located in the cooling cavity.

10. A server, comprising an element to be cooled and the heat dissipation device according to claim 1, wherein the heat dissipation device is provided on the element to be cooled.
